(19) United States
(12) Patent Application Publication
(10) Pub. No.: US 2011/0090010 A1
(43) Pub. Date: Apr. 21, 2011

(54) Variable gain amplification device

(75) Inventor: Hirokazu Oyabu, Kanagawa (JP)

(73) Assignee: Renesas Electronics Corporation, Kawasaki (JP)

(21) Appl. No.: 12/923,984

(22) Filed: Oct. 19, 2010

(30) Foreign Application Priority Data
Oct. 20, 2009 (JP) 2009-241118
Nov. 11, 2009 (JP) 2009-258093
Aug. 30, 2010 (JP) 2010-191851

(51) Int. Cl. H03G 3/30

(52) U.S. Cl. 330/284

(57) ABSTRACT

Provided is a variable gain amplification device that suppresses deterioration of a noise characteristic generated according to an amount of attenuation by fixing the amount of attenuation while a variable gain amplification unit is changing a gain. The variable gain amplification device includes a variable attenuation unit that attenuates an input signal. The variable gain amplification device further includes a variable gain amplification unit that changes and amplifies a gain of the attenuated input signal which is output by the variable attenuation unit. A control unit is further included that controls to fix the amount of attenuation of the variable attenuation unit while the variable gain amplification unit is changing the gain.

### INCORPORATION BY REFERENCE

This application is based upon and claims the benefit of priority from Japanese patent application No. 2009-241118 filed on Oct. 20, 2009, No. 2009-258093 filed on Nov. 11, 2009 and No. 2010-191851 filed on Aug. 30, 2010, the disclosure of which is incorporated herein in its entirety by reference.

### BACKGROUND

1. Field of the Invention

The present invention relates to a variable gain amplification device, and particularly to a variable gain amplification device that involves attenuation of an input signal.

2. Description of Related Art

In receivers such as a communication device and a TV, various reception radio wave statuses are assumed. Such a system receives signals of wide range signal strength. Therefore, the signal strength is adjusted to be appropriate signal strength by a variable gain amplification device, and then signal processes such as demodulation is performed. Thus, the variable gain amplification device requires a wide range variable gain. Further, a weak desired radio wave may exist in a strong jamming. In order to ensure the reception performance in this case, the variable gain amplification device must have low noise and low distortion.

A configuration of a commonly used amplifier is described with reference to FIG. 16. An input signal is supplied to a variable gain amplifier 102 and a variable gain amplifier 103 which is cascaded to a fixed attenuator 104. A summer unit 105 adds output current output by the variable gain amplifiers 102 and 103, and outputs the added current to a current-to-voltage conversion circuit 106. The current-to-voltage conversion circuit 106 generates and outputs an output signal (output voltage). FIG. 17 illustrates a configuration example of the variable gain amplifiers 102 and 103. The variable gain amplifiers 102 and 103 include transistors 107 and 108. The current of the current source connected to the transistors 107 and 108 shall be Ic_a or Ic_b. The variable gain amplifiers 102 and 103 can change a gain by controlling the current Ic_a or Ic_b of the differential pair. The maximum output current of the gain amplifiers is proportional to Ic_a or Ic_b. Although FIG. 17 illustrates the example of the differential amplifier, it will be similar in the case of a single amplifier.

Next, a control scheme and characteristics of the variable gain amplifier 102 and 103 are explained with reference to FIGS. 18A to 18C. FIG. 18A illustrates the control scheme of the variable gain amplifiers 102 and 103. A control circuit 101 continuously switches the control current Ic_a and Ic_b for the variable gain amplifiers 102 and 103 according to a control signal 100. When the control current Ic_a is reduced according to the control signal, the gain of the variable gain amplifier 102 will also be reduced. If the control current Ic_b is increased, the gain of the variable gain amplifier 103 will also be increased. Since a fixed attenuator 104 is cascaded to the variable gain amplifier 103, the gain of the added output current is reduced only by an amount of attenuation attenuated by the fixed attenuator 104. A change in the gain for the control signal is illustrated in FIG. 18B. The variable range of the gain is determined by the amount of attenuation of the fixed attenuator 104.

Next, a configuration of a variable gain amplification device disclosed in Japanese Unexamined Patent Application Publication No. 2004-328425 is explained with reference to FIG. 20. The variable gain amplification device includes a variable attenuator 111 that controls an amount of attenuation of a signal by an attenuator control signal, and a variable gain amplifier 112 that controls a gain by an amplification control signal. The variable attenuator 111 and the variable gain amplifier 112 are cascaded. The variable gain amplification device further includes a control circuit 110 that generates the attenuator control signal and the amplifier control signal according to a control signal supplied from outside. The control by this control circuit 110 is illustrated in FIGS. 21A to 21C. A change in the gain of the variable gain amplifier 112 is illustrated in FIG. 21A. A change in the amount of attenuation of the variable attenuator 111 is illustrated in FIG. 21B. By changing the gain of the variable gain amplifier 112, and simultaneously changing the amount of attenuation of the variable attenuator 111 according to the control signal supplied to the control circuit 110, the gain of the variable gain amplification device is changed according to the control signal supplied to the control circuit, and is illustrated in FIG. 21C.

### SUMMARY

The present inventor has found a problem in the amplifier explained in FIG. 16 that a distortion characteristic changes when controlled by the control scheme illustrated in FIG. 18A, as illustrated in FIG. 18C. Specifically, there is a problem of fluctuating a 1 dB compression point. The fluctuation of the 1 dB compression point is explained with reference to FIG. 19A to 19B. FIG. 19A illustrates input and output characteristics in a maximum gain state and a minimum gain state. The input and output characteristics in the maximum gain state and the minimum gain state are characteristics parallel to each other with a difference of the amount of attenuation of the fixed attenuator 104. As illustrated in FIG. 19A, the 1 dB compression points in the maximum gain state and the minimum gain state indicate the same value (dBm). Next, as illustrated in FIG. 18C, the input and output characteristics in the status in which the distortion characteristic deteriorates are illustrated in FIG. 19B. FIG. 19B illustrates characteristics of each of the variable gain amplifiers 102 and 103 alone for the purpose of the explanation. The variable gain amplifier 102 has a small gain, and the control current Ic_a is also low. Therefore, the output is saturated at lower output as compared to the maximum gain state. On the other hand, as for the variable gain amplifier 103, the control current Ic_b is greater as compared to the control current Ic_a, and the gain is also large. Therefore, the variable gain amplifier 103 is saturated at higher output than the variable gain amplifier 102. When the output from these two amplifiers are added with care that the vertical axis is a logarithm, the characteristics exhibit will be the ones illustrated in FIG. 19B. It can be seen from FIG. 19B that inflection point exists in the middle of the output characteristic in the middle gain state. When calculating the 1 dB compression point from this output characteristic, the 1 dB compression point will be lower in the middle gain state than in the maximum gain state. In order to obtain a wide gain variable range as a variable gain device, it is necessary to increase the amount of attenuation of the fixed attenuator. However the deterioration of the distortion characteristic is generally proportional to the amount of attenuation of the fixed attenuator. It is known that such problem occurs in the method to switch control current of the gain amplifier using the fixed attenuator. The amplifier using such method cannot have both of the wide gain range and the low distortion characteristic.

When the variable gain amplification device illustrated in FIG. 20 operates by the control scheme of FIGS. 21A to 21C, it is possible to suppress the deterioration of the distortion characteristic because the control scheme of FIGS. 21A to 21C does not switch the variable amplifiers by the control current. However, in that case, the present inventor has found a problem that noise characteristic deteriorates. Generally, if an attenuator is connected to a previous stage of an amplifier, and a gain is reduced by changing the amount of attenuation, the noise characteristic will also deteriorate in proportion to the amount of attenuation. The amount of deterioration is greater than the case of changing the gain in the circuit configuration inside the amplifier. As for the amplifier of FIG. 16, in the region where the maximum gain state is obtained, the gain is obtained only from the variable gain amplifier 102. Thus the noise characteristic does not deteriorate by connecting the fixed attenuator 104. However, as for the variable gain amplification device of FIG. 20, an input signal is supplied to the variable gain amplifier 112 via the variable attenuator 111 also in the region where the maximum gain state is obtained. Therefore, the noise characteristic of the variable gain amplification device of FIG. 20 largely deteriorates in the region where the maximum gain state is obtained as compared to the amplifier of FIG. 16.

A first exemplary aspect of the present invention is a variable gain amplification device that includes a variable attenuation unit that attenuates an input signal, a first variable gain amplification unit that amplifies and changes a gain of the attenuated input signal, in which the input signal is output by the variable attenuation unit, and a control unit that controls to fix an amount of attenuation of the variable attenuation unit in a first control region in which the first variable gain amplification unit changes the gain.

Such a variable gain amplification device can control the variable attenuation unit and the variable gain amplification unit, and also control the gain of the entire variable gain amplification device.

The present invention provides the variable gain amplification device that suppresses the deterioration of the noise characteristic generated according to the amount of attenuation by fixing the amount of attenuation while the variable gain amplification unit is changing the gain.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a block diagram of a variable gain amplification device according to a first exemplary embodiment;

FIG. 2 illustrates control content of a control circuit according to the first exemplary embodiment;

FIG. 3 is a block diagram of the variable gain amplification device according to the first exemplary embodiment;

FIG. 4 illustrates a noise characteristic according to the first exemplary embodiment;

FIG. 5 is a block diagram of the variable gain amplification device according to a second exemplary embodiment;

FIG. 6 is a block diagram of the variable gain amplification device according to the second exemplary embodiment;

FIG. 7 is a block diagram of a control circuit according to a third exemplary embodiment;

FIG. 8 is a block diagram of a variable gain amplification device according to the third exemplary embodiment;

FIG. 9 illustrates control content of the control circuit according to the third exemplary embodiment;

FIG. 10 is a block diagram of a variable attenuator according to other exemplary embodiment;

FIG. 11 is a block diagram of the variable attenuator according to other exemplary embodiment;

FIG. 12 is a block diagram of the variable attenuator according to other exemplary embodiment;

FIG. 13 is a block diagram of a variable gain amplifier according to other exemplary embodiment;

FIG. 14 is a block diagram of the variable gain amplifier according to other exemplary embodiment;

FIG. 15 is a block diagram of the variable gain amplifier according to other exemplary embodiment;

FIG. 16 is a block diagram of a commonly used amplifier;

FIG. 17 is a block diagram of a variable gain amplifier included in the commonly used amplifier;

FIGS. 18A to 18C illustrate control operation of the commonly used amplifier;

FIGS. 19A and 19B illustrate output characteristics of the commonly used amplifier;

FIG. 20 is a block diagram of a variable gain amplification device according to Japanese Unexamined Patent Application Publication No. 2004-328425;

FIGS. 21A to 21C illustrate control operation of the variable gain amplification device according to Japanese Unexamined Patent Application Publication No. 2004-328425;

FIG. 22 is a block diagram of a control circuit according to a fourth exemplary embodiment;

FIG. 23 is a graph illustrating a relationship between conductance and a control voltage according to the fourth exemplary embodiment;

FIG. 24 is a graph illustrating a relationship between the conductance and the control voltage when using the control circuit according to the third exemplary embodiment;

FIG. 25 is a block diagram of a control circuit according to a fifth exemplary embodiment; and

FIG. 26 is a graph illustrating a relationship between conductance and a control voltage according to the fifth exemplary embodiment.

### DETAILED DESCRIPTION OF THE EXEMPLARY EMBODIMENTS

### First Exemplary Embodiment

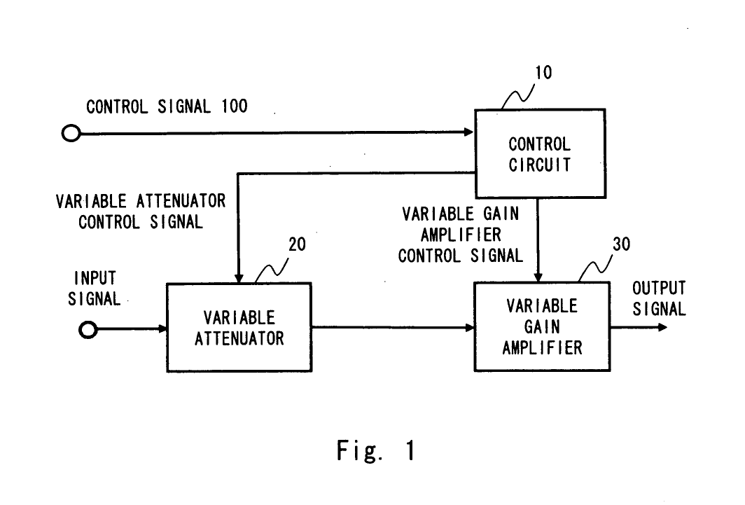

Hereinafter, exemplary embodiments of the present invention are described with reference to the drawings. A configuration example of a variable gain amplification device according to a first exemplary embodiment of the present invention is explained with reference to FIG. 1. The variable gain amplification device includes a control circuit 10, a variable attenuator 20, and a variable gain amplifier 30.

The control circuit 10 receives a control signal 100, and generates a variable attenuator control signal, which is output to the variable attenuator 20 according to the control signal 100, and a variable gain amplifier control signal, which is output to the variable gain amplifier 30. The control signal may be a control voltage composed of a voltage, for example. The variable attenuator 20 receives an input signal and attenuates the input signal. The input signal is to be attenuated and controlled of its gain to obtain the gain. The variable attenuator 20 outputs the attenuated input signal to the variable gain amplifier 30, which is cascaded to the variable attenuator 20. The variable gain amplifier 30 amplifies the input signal received from the variable attenuator 20 according to the variable gain amplifier control signal, and generates an output signal.

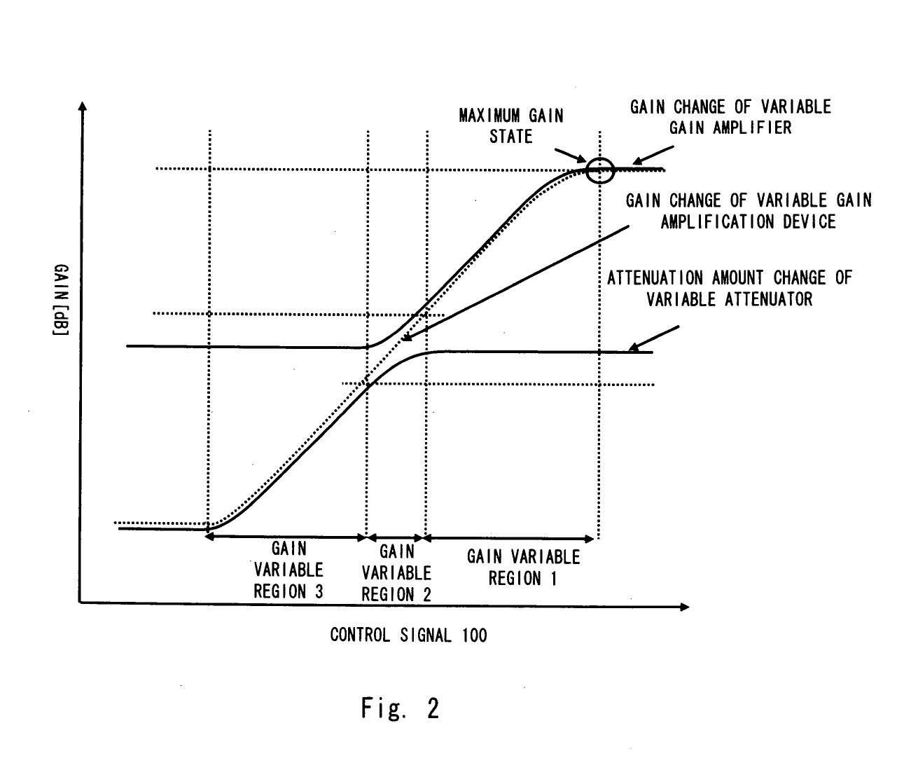

Next, a control operation of the control circuit 10 according to the first exemplary embodiment of the present invention is explained with reference to FIG. 2. In FIG. 2, the horizontal axis indicates the size of the control signal 100, and the vertical axis using the logarithmic axis indicates the gain. The control circuit 10 controls the variable attenuator 20 and the variable gain amplifier 30 to obtain a greater gain as the size of the control signal 100 is increased. The region where the value of the gain is reduced by a certain value from a maximum gain state is referred to as a gain variable region 1. Specifically, the gain variable region 1 is a region where the gain of the variable gain amplification device is changed while changing the gain of the variable gain amplifier 30. For example, the region where the gain is reduced by ¼ from the maximum gain state shall be the gain variable region 1. Further, the region where the value of the gain is increased by a certain value from a minimum gain status is referred to as a gain variable region 3. Specifically, the gain variable region 3 is a region where the gain of the variable gain amplification device is changed while fixing the gain of the variable gain amplifier 30. For example, the region where the gain is increased by ¼ from the minimum gain state shall be the gain variable region 3. Furthermore, the region between the gain variable region 1 and the gain variable region 3 is referred to as a gain variable region 2. Specifically, the gain variable region 2 is a region to shift the gain of the variable gain amplification device from the gain variable region 3 to the gain variable region 1.

In the gain variable region 1, the control circuit 10 allows the gain of the variable gain amplifier device to be variable by changing the gain of the variable gain amplifier 30, and does not change the amount of attenuation of the variable attenuator 20 by keeping it to the minimum. In the gain variable region 3, the control circuit 10 allows the gain of the variable gain amplification device to be variable by changing the amount of attenuation of the variable attenuator 20, and does not change the gain of the variable gain amplifier 30 by keeping it to the minimum. In the gain variable region 2, the control circuit 10 changes a part of the gain in the gain variable range of the variable gain amplifier 30, and allows the gain of the variable gain amplification device to be variable by changing a part of the amount of attenuation in the amount of attenuation variable range of the variable attenuator 20.

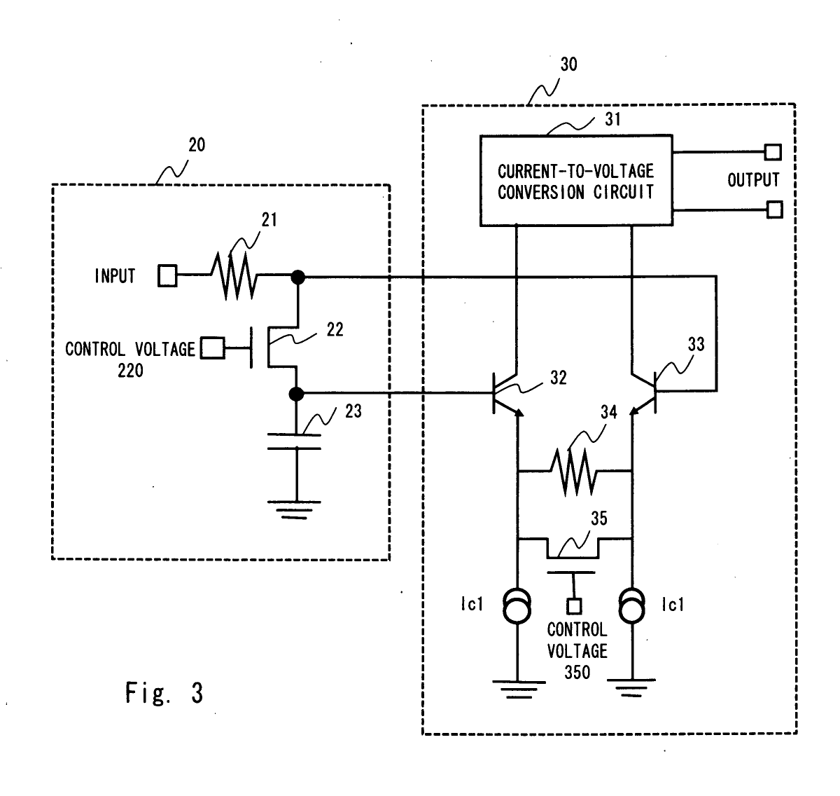

Next, a configuration example of the variable attenuator 20 and the variable gain amplifier 30 according to the first exemplary embodiment of the present invention is explained with reference to FIG. 3. The variable attenuator 20 includes a resistor 21, a MOS transistor 22, and a capacitor 23. The resistor 21 is connected to an input terminal of the variable attenuator 20. Moreover, either the source or the drain of the MOS transistor 22 is connected to the resistor 21, and the remaining one of the source or the drain is connected to the capacitor 23 and grounded.

The variable gain amplifier 30 includes a current-to-voltage conversion circuit 31, bipolar transistors 32 and 33, a resistor 34, and a MOS transistor 35. The base of the bipolar transistor 32 is connected to the MOS transistor 22 and the capacitor 23 of the variable attenuator 20. Further, the base of the bipolar transistor 33 is connected to the resistor 21 and the MOS transistor 22 of the variable attenuator 20. The resistor 34 and the MOS transistor 35 are connected to the emitters of the bipolar transistors 32 and 33.

Next, an operation of the variable attenuator 20 and the variable gain amplifier 30 is explained. The MOS transistor 22 of the variable attenuator 20 receives a control voltage 220. The control voltage 220 is the same as the variable attenuator control signal received from the control circuit 10. The MOS transistor 22 can change the amount of attenuation by the resistor 21 and the MOS transistor 22 by changing the control voltage 220 to receive. For example, if the control voltage 220 is increased, the source-to-drain resistance of the MOS transistor 22 is controlled to be low. Then, the signal output to the base of the bipolar transistor 33 of the variable gain amplifier 30 becomes small. Thus the variable attenuator 20 realizes the operation to increase the amount of attenuation. Further, the signal output to the base of the bipolar transistor 32 is set to a fixed value by the capacitor 23.

The MOS transistor 35 of the variable gain amplifier 30 receives a control voltage 350. The control voltage 350 is the same as the variable gain amplifier control signal received from the control circuit 10. The MOS transistor 35 can change the source-to-drain resistance of the MOS transistor 35, which is emitter resistance of the bipolar transistors 32 and 33 by changing the received control voltage 350. For example, when the control voltage 350 is increased, the source-to-drain resistance of the MOS transistor 35 is controlled to be low. Then, the signal output by the current-to-voltage conversion circuit 31 is increased, and thereby realizing the amplification operation. Accordingly, conductance of the bipolar transistors 32 and 33 is changed without changing a bias current Ic 1, and a differential voltage is output via the current-to-voltage conversion circuit 31.

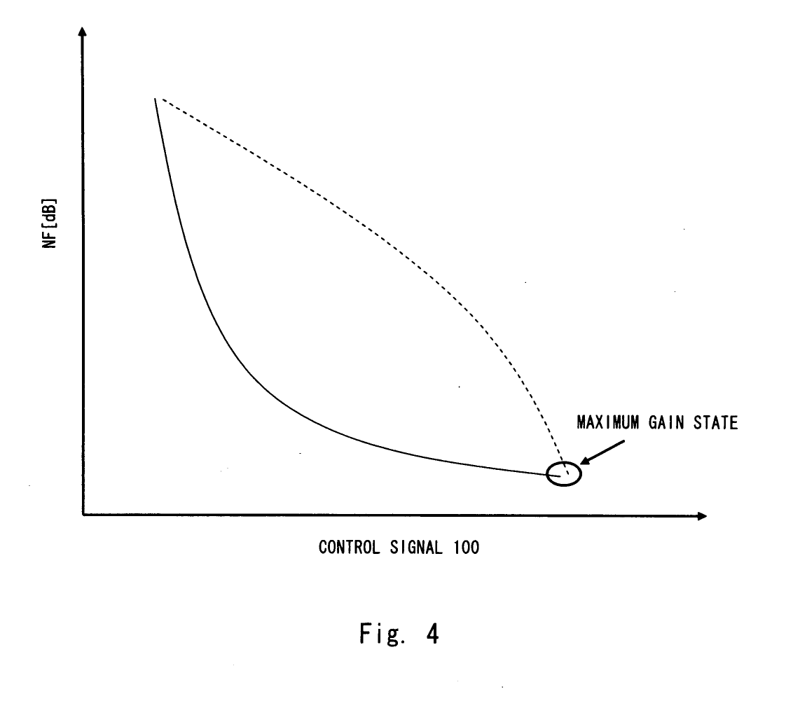

As explained above, the variable gain amplification device according to the first exemplary embodiment of the present invention achieves the following exemplary advantages. In the gain variable region 1, the gain of the variable gain amplifier 30 is changed and the amount of attenuation of the variable attenuator 20 is fixed to the minimum. This enables suppression of the deterioration of the noise characteristic generated according to the increase in the amount of attenuation of the variable attenuator 20. FIG. 4 illustrates the state of suppressing the deterioration of the noise characteristic in the gain variable region 1. In FIG. 4, the dashed line indicates the case of changing the amount of attenuation of the variable attenuator 20, and the solid line indicates the case of fixing the amount of attenuation of the variable attenuator 20. As illustrated in FIG. 4, the noise characteristic in the gain variable region 1 is improved by performing the abovementioned control.

The gain variable range of the variable gain amplification device can be expanded by changing the amount of attenuation of the variable attenuator 20 in the gain variable regions 2 and 3. Further, if the gain variable range required for the variable amplification device is set constant, the gain variable range required for the variable gain amplifier 30 can be narrowed by the amount of attenuation of the variable attenuator 20.

In the variable gain system according to the first exemplary embodiment of the present invention, as the control is not performed to change the gain by switching control current of a plurality of gain amplifiers, there is no deterioration of the distortion characteristic.

### Second Exemplary Embodiment

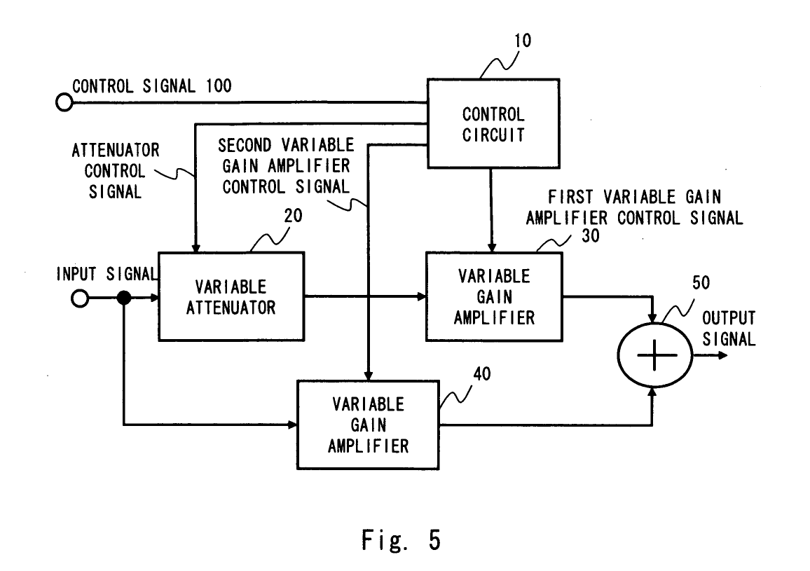

Next, a configuration example of a variable gain amplification device according to a second exemplary embodiment of the present invention is explained with reference to FIG. 5. In addition to the configuration of FIG. 1, the variable gain amplification device according to the second exemplary embodiment of the present invention further includes a variable gain amplifier 40 and an summer unit 50.

The variable gain amplifier 40 receives an input signal, is controlled by a second variable gain amplifier control signal obtained from the control circuit 10, and outputs the input signal with controlled gain to the summer unit 50.

The summer unit 50 adds the output signals with amplified gain which are obtained from the variable gain amplifier 30 and the variable gain amplifier 40. Then, an output signal of the variable gain amplification device is generated.

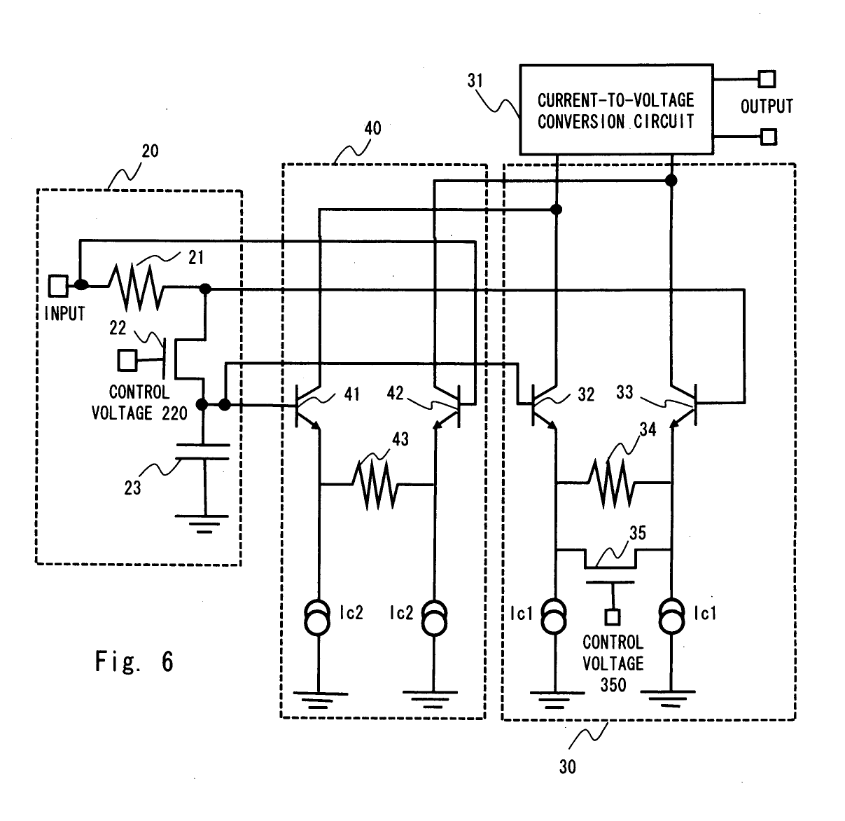

Next, a configuration example of the variable attenuator 20, and the variable gain amplifiers 30 and 40 of the variable gain amplification device according to the second exemplary embodiment of the present invention are explained with reference to FIG. 6. In addition to the configuration of FIG. 3, the variable gain amplification device of FIG. 6 further includes bipolar transistors 41 and 42 which form the variable gain amplifier 40, and a resistor 43. The current-to-voltage conversion circuit 31 is equivalent to the summer unit 50.

The input signal before being attenuated by the resistor 21 of the variable attenuator 20 is supplied to the base of the bipolar transistor 42. The bipolar transistor 41 receives the signal, which is set to a fixed value by the capacitor 23. In such a configuration, collector current of the bipolar transistors 41 and 42 is changed by changing bias current Ic2 which is connected to the emitters of the bipolar transistors 41 and 42. The bias current Ic2 is controlled by the second variable gain amplifier control signal from the control circuit 10. Accordingly, the variable gain amplifier 40 can change the gain.

Although FIG. 6 illustrates the example of adding the collector current of the bipolar transistors 41 and 42 and the collector current of the bipolar transistors 32 and 33 and supplying the added collector current to the current-to-voltage conversion circuit, after converting the collector current of the bipolar transistors 41 and 42 into a voltage, the voltage may be added to the voltage output by the variable gain amplifier 30.

In addition to the control according to the first exemplary embodiment, the control circuit 10 performs the control to switch the amplification operation from the variable gain amplifier 30 to the variable gain amplifier 40 by reducing the gain of the variable gain amplifier 30 from the maximum gain state of the variable gain amplifier 30 and increasing the gain of the variable gain amplifier 40. More specifically, the control circuit 10 controls the control voltages 220 and 350 of FIG. 6 so that the gain of the variable gain amplifier 30 reaches its maximum, the amount of attenuation of the variable attenuator 20 reaches its minimum, the bias current Ic2 is increased, and the bias current Ic1 is reduced. The control of the bias currents Ic1 and Ic2 may be performed according to the first variable gain amplifier control signal and the second variable gain amplifier control signal, which are output by the control circuit 10. Alternatively, an additional control signal may be included only for controlling the bias current Ic1 and Ic2.

In the configuration of FIG. 1, as the variable attenuator 20 is connected to the previous stage of the variable gain amplifier 30, even in the maximum gain state, the deterioration of the noise characteristic by the attenuation effect of the variable attenuator 20 is unavoidable. However, in the maximum gain state, by switching the operation to the variable gain amplifier 40 with no circuit connected to the previous stage, the deterioration of the noise characteristic can be further suppressed. As this control scheme switches the variable gain amplifier 30 and the variable gain amplifier 40 by the control circuit 10, there may be the deterioration of the distortion characteristic. However, as for the variable gain amplifiers 30 and 40 according to the second exemplary embodiment of the present invention, since the switching is performed in the maximum gain state, the amount of attenuation of the variable attenuator 20 is fixed to the minimum. This enables suppression of the deterioration of the distortion characteristic generated in proportion to the amount of attenuation.

### Third Exemplary Embodiment

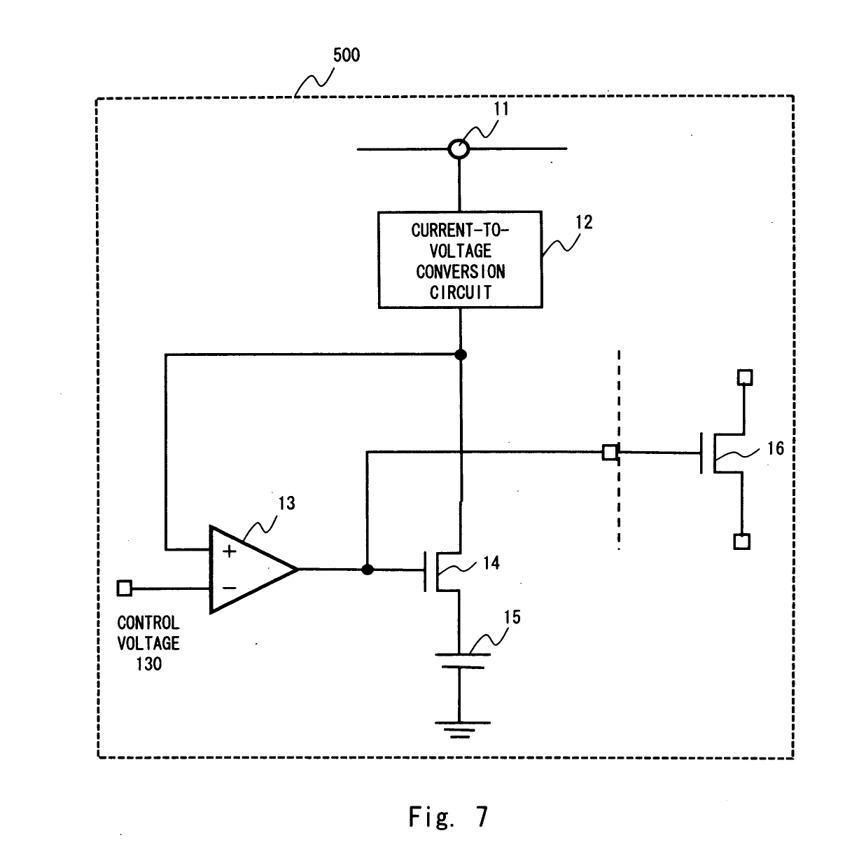

Next, a configuration example of the control circuit 500 according to a third exemplary embodiment of the present invention is explained with reference to FIG. 7. The control circuit 10 can be composed by using the control circuit 500. The control circuit 500 includes a power supply unit 11, a current-to-voltage conversion circuit 12, an operational amplifier 13, a MOS transistor 14, a bias power supply 15, and a MOS transistor 16. The current-to-voltage conversion circuit 12, the MOS transistor 14, and the bias power supply 15 are connected in series between the power supply unit 11 and a GND power supply. Further, the operational amplifier 13 receives a voltage at a node of the MOS transistor 14 and the current-to-voltage conversion circuit 12, and the control voltage 130, and outputs a gate voltage to the MOS transistor 14 and the MOS transistor 16. In this configuration, the MOS transistor 16 is to be controlled, and the MOS transistor 14 operates as a replica of the MOS transistor 16. The MOS transistor 16 is used by the MOS transistor 22 of the variable attenuator 20 or the MOS transistor 35 of the variable gain amplifier 30. An operation of the control circuit 500 is explained hereinafter.

In response to the control voltage 130 which is to be variably controlled, the operational amplifier 13 outputs the variably controlled gate voltage to the MOS transistor 14. In response to the variably controlled gate voltage, the MOS transistor 14 generates source-to-drain current. The source-to-drain current is converted into a voltage by the current-to-voltage conversion circuit 12. The voltage converted by the current-to-voltage conversion circuit 12 is controlled by feedback control of the operational amplifier 13 to be equal to the control voltage 130. In this way, the output voltage generated by the change in the voltage supplied to positive and negative terminals of the operational amplifier 13 is output to the gates of the MOS transistors 14 and 16, and the source-to-drain resistance of the MOS transistors 14 and 16 is variably controlled. The source-to-drain resistance of the MOS transistor 16, which is to be controlled, is controlled using the MOS transistor 14, the replica. Thus the source-to-drain resistance of the MOS transistor 16 is accurately controlled without influence of environmental fluctuation and process variation. The control error of the MOS transistors 14 and 16 can be suppressed by connecting the MOS transistor 14 to the bias power supply 15 that supplies the same value as the source voltage of the MOS transistor 16.

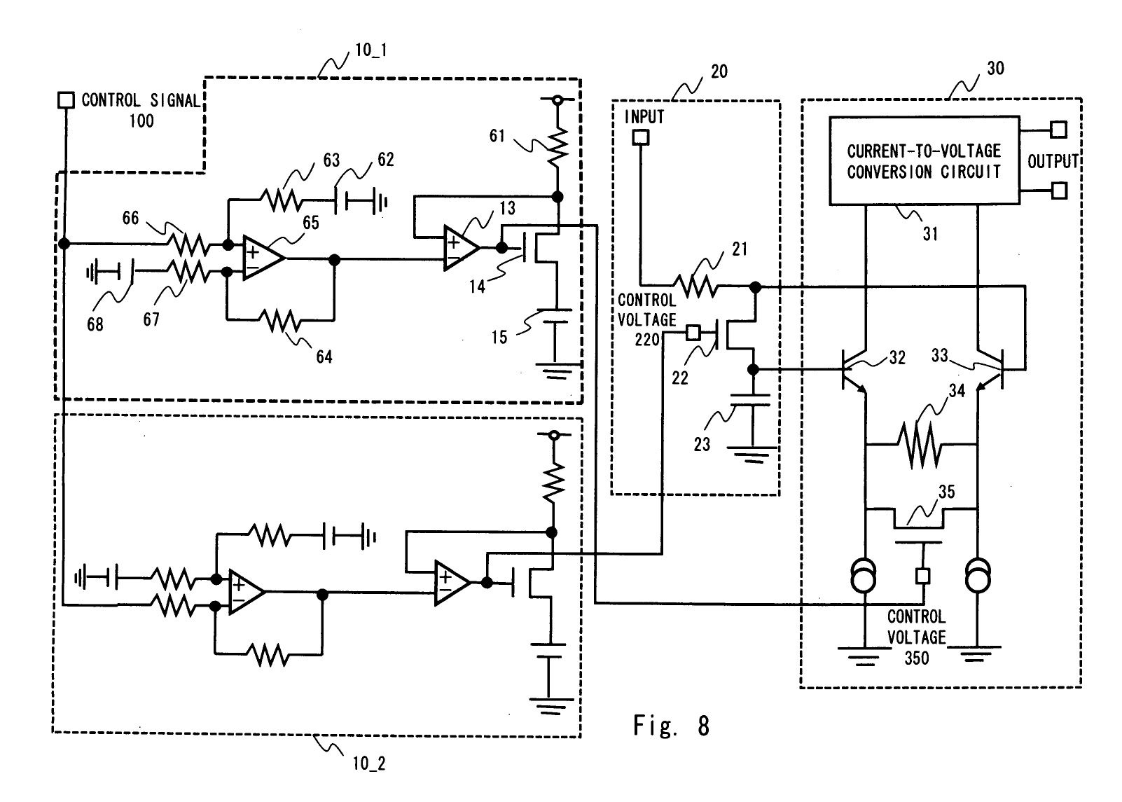

Next, a configuration example of the variable gain amplification device when applying the control circuit of FIG. 7 to the configuration of FIG. 3 is explained with reference to FIG. 8. As the configuration of the variable attenuator 20 and the variable gain amplifier 30 is same as FIG. 3, the explanation is omitted. The control circuit 10 is composed by a control circuit 10_1 and 10_2. A control circuit 10_1 is connected to the gate of the MOS transistor 35 of the variable gain amplifier 30. A control circuit 10_2 is connected to the gate of the MOS transistor 22 of the variable attenuator 20. Since the control circuit 10_1 and the control circuit 10_2 have the same configuration, the configuration example of the control circuit 10_1 is explained hereinafter.

In addition to the configuration of FIG. 7, the control circuit 10_1 further includes bias power supplies 62 and 68, resistors 63, 64, 66, and 67, and an operational amplifier 65. The resistor 61 is equivalent to the current-to-voltage conversion circuit 12. The negative terminal of the operational amplifier 13 receives the signal output by the operational amplifier 65. The control circuit 10_1 obtains the control signal 100, and receives a signal determined by the bias power supply 62 and the resistors 63 and 66 into a positive terminal of the operational amplifier 65. The control circuit 10_1 outputs an output voltage amplified by the resistors 64 and 67, which are connected to a negative terminal of the operational amplifier 65, to the negative terminal of the operational amplifier 13. Same control is carried out also in the control circuit 10_2. In the control circuit 10_2, the obtained control signal 100 is supplied to the negative terminal of the operational amplifier, which is equivalent to the operational amplifier 65. Accordingly, the more the size of the control signal 100 is increased, the smaller the size of the signal output by the operational amplifier, which is equivalent to the operational amplifier 65.

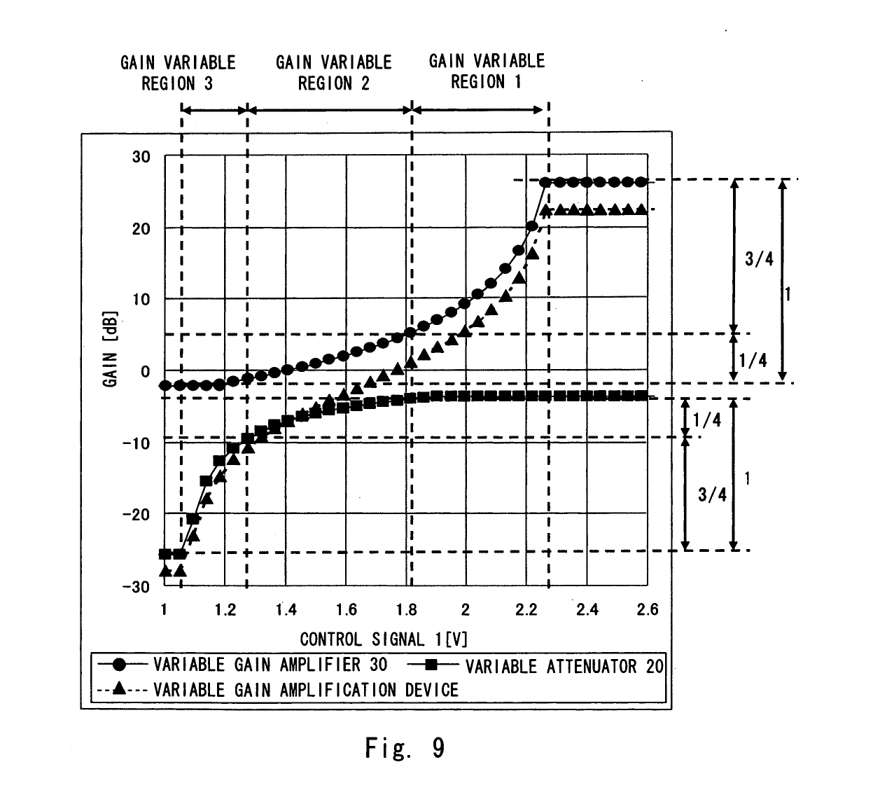

The amount of attenuation and the gain of the variable attenuator 20 and the variable gain amplifier 30 are controlled by the control voltages 220 and 350, which are output by the operational amplifier 13 of the control circuit 10_1, and the operational amplifier (equivalent to the operational amplifier 13) of the control circuit 10_2. A change in the gain of the variable gain amplification device in this case is explained with reference to FIG. 9.

The control circuit 10 simultaneously changes the gain by ¼ of the variable gain range in the logarithmic axis of the variable gain amplifier 30 and changes the amount of attenuation by ¼ of the amount of attenuation variable range in the logarithmic axis of the variable attenuator 20. The amount of attenuation of the variable attenuator 20 changes according to the source-to-drain resistance of the MOS transistor 22, and the gain of the variable gain amplifier 30 changes according to the source-to-drain resistance of the MOS transistor 35. As described so far, in the gain variable region 2, the variable attenuator 20 and the variable gain amplifier 30 complementarily control the amount of attenuation and the gain. This improves the linearity of the change in the gain of the variable gain amplification device.

### Fourth Exemplary Embodiment

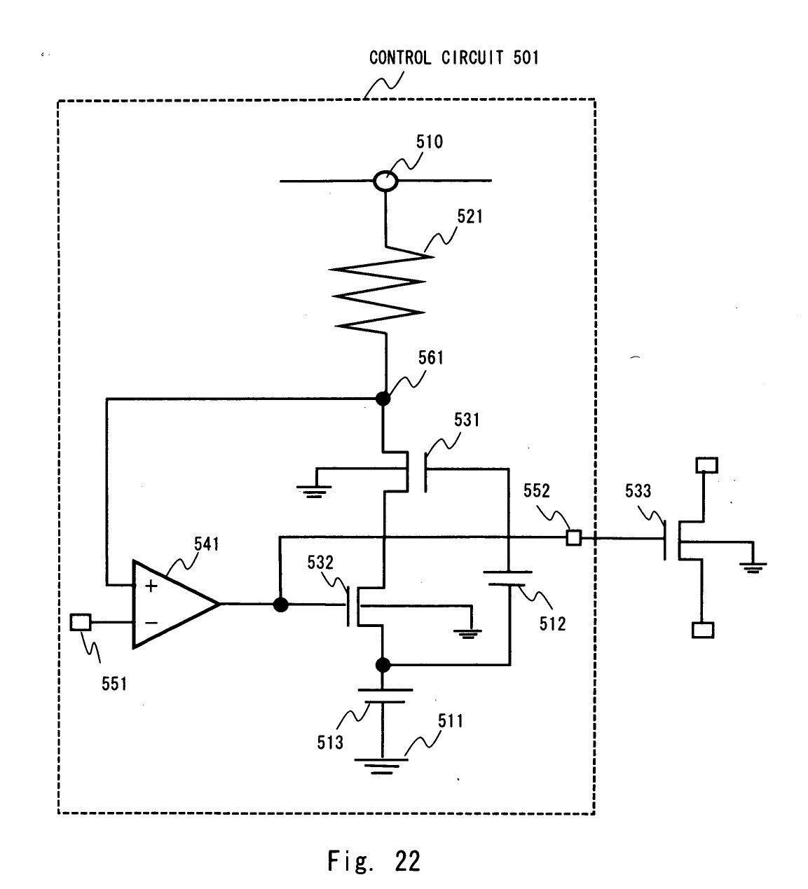

A configuration example of a control circuit 501 according to a fourth exemplary embodiment of the present invention is described with reference to FIG. 22. The control circuit 10 can be composed by using the control circuit 501. The control circuit 501 includes a power supply (VCC) 510, a power supply (GND) 511, bias power supplies 512 and 513, a resistor 521, MOS transistors 531 and 532, an operational amplifier 541, an input terminal 551, an output terminal 552, and a node 561. A MOS transistor is explained as an NMOS transistor, for example.

The resistor 521 and the MOS transistors 531 and 532 are connected in series between the power supply (VCC) 510 and the power supply (GND) 511. The resistor 521 is connected to the power supply (VCC) 510. Further, the bias power supply 513 is connected between the MOS transistor 532 and the power supply (GND) 511. The MOS transistor 531 is connected between the resistor 521 and the MOS transistor 532.

One side of the output terminal 552 is connected to the operational amplifier 541 and the MOS transistor 532. The other side of the output terminal 552 is connected to the gate of the MOS transistor 22 of the variable attenuator 20, or the MOS transistor 35 of the variable gain amplifier 30.

The node 561 outputs a voltage at a node of the resistor 521 and the MOS transistor 531 to the positive terminal side of the operational amplifier 541. Further, the operational amplifier 541 receives the control voltage into the negative terminal side from the input terminal 551. The control voltage can be set variable. The operational amplifier 541 outputs a voltage to the MOS transistor 532 according to the voltage received into the positive and negative terminals. The operational amplifier 541 outputs the same voltage also to the output terminal 552 while outputting the voltage to the MOS transistor 532.

The bias power supply 512 outputs a voltage to the gate of the MOS transistor 531 so that the MOS transistor 531 operates in a saturation region. As an example, the bias power supply 512 outputs the voltage to the gate of the MOS transistor 531 in order to satisfy the relationship of Vds>2(Vgs-Vth), where Vds is a source-to-drain voltage, Vgs is a gate-to-source voltage, and Vth is a threshold voltage of the MOS transistor 531. When the MOS transistor 531 operates in the saturation region, the potential of the source of the MOS transistor 531, which is the drain of the MOS transistor 532, is substantially fixed.

The bias power supply 512 is connected to the source of the MOS transistor 532 so that the MOS transistor 532 may be operated in a linear area. As an example, the bias setting is configured so as to satisfy the condition of Vds<<2(Vgs−Vth) in which Vds is low. Further, the bias power supply 513 is connected so that the source of the MOS transistor 532 will have the same potential as the source of the MOS transistor 22 of the variable attenuator 20 or the source of the MOS transistor 35 of the variable gain amplifier 30. The MOS transistor 533 operates the MOS transistor 532 as a replica and controls the resistance to be variable. The MOS transistor 533 receives the voltage output by the output terminal 522 into the gate.

Next, an operation of the control circuit 501 is explained. The control circuit 501 controls the MOS transistor 532 using feedback from the operational amplifier 541. When a control voltage Vcnt input into the input terminal 551 is set variable, the node 561 is feedback-controlled so that a voltage equivalent to the control voltage Vcnt is generated. If the resistance of the resistor 521 is R521, and the current generated in the resistor 521 is Ic521, Ic521 can be obtained by the following equation 1.

Ic521=(VCC−Vcnt)/R521 (equation 1)

When the MOS transistor 531 operates in the saturation region, even if Ic521 changes, the source-to-drain voltage Vds of the MOS transistor 532 stays constant. Therefore, the source-to-drain conductance g of the MOS transistor 532 (an inverse number of the source-to-drain resistance of the MOS transistor 532) can be obtained by the following equation 2.

g=Ic521/Vds (equation 2)

Since the source-to-drain voltage Vds of the MOS transistor 532 is constant, the source-to-drain conductance g of the MOS transistor 532 changes in proportion to Ic521. Based on the equations 1 and 2, the source-to-drain conductance g of the MOS transistor 532 is defined by the following equation 3.

g=(VCC−Vcnt)/(R521×Vds) (equation 3)

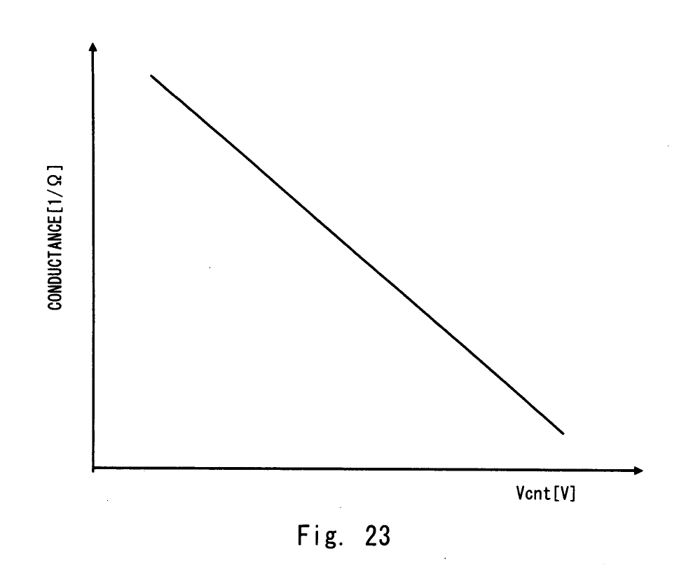

Accordingly, the source-to-drain conductance g of the MOS transistor 532 is variably controlled according to the value of a control voltage Vcnt input into the input terminal 551. A slope of the change in the source-to-drain conductance g of the MOS transistor 532 is determined to be constant in proportion to 1/R521. FIG. 23 illustrates a relationship between the source-to-drain conductance g of the MOS transistor 532 and the control voltage Vcnt. FIG. 23 illustrates the state in which the source-to-drain conductance g of the MOS transistor 532 changes linearly according to the control voltage Vcnt.

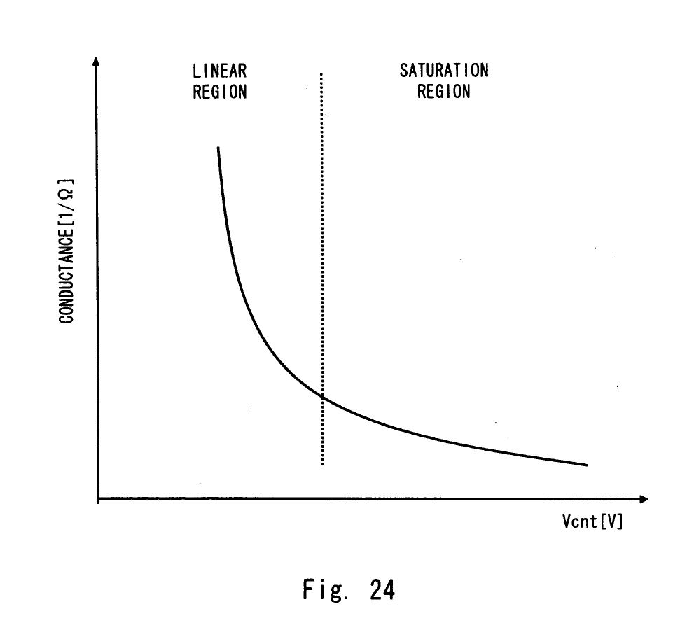

As explained above, the control circuit 501 according to the fourth exemplary embodiment of the present invention allows the source-to-drain voltage of the MOS transistor 532 to be fixed to a substantially constant value. Therefore, the MOS transistor 532 can continue the operation in the linear area regardless of the change in the current Ic521 generated in the resistor 521. Thus, the slope of the change in the source-to-drain conductance of the MOS transistor 532 can be constant for the control voltage Vcnt. In other words, the source-to-drain conductance of the MOS transistor 532 can be linearly controlled. Accordingly, the change in the source-to-drain conductance of the MOS transistor 533, which is connected to the operational amplifier 541, can also be linearly controlled in a similar manner. On the other hand, if the control circuit 500 of FIG. 7 is used, when the source-to-drain resistance of the MOS transistor 14 is low, the source-to-drain voltage of the MOS transistor 14 is low and the MOS transistor 14 operates in the linear region. However, the source-to-drain voltage of the MOS transistor 14 is fluctuated by the change in the current flowing into the MOS transistor 14. Therefore, the source-to-drain conductance of the MOS transistor 14 does not change with a constant slope for the control voltage. Further, if the source-to-drain resistance of the MOS transistor 14 is high, the MOS transistor 14 operates in the saturation region. Therefore, the slope of the change in the source-to-drain resistance of the MOS transistor 14 for the control voltage largely changes. In connection with this, the MOS transistor 16 connected to the operational amplifier 13 has similar characteristics. FIG. 24 illustrates a relationship between the source-to-drain conductance of the MOS transistor 104 and the control voltage. Accordingly, the control circuit 501 has a wider resistance value variable range than the control circuit 500, and the conductance linearly changes for the control voltage. This realizes a variable resistor using the MOS transistor with high resistance value controllability. Therefore, the control circuit 501 can expand the variation width of the variable gain and the amount of variable attenuation.

As mentioned above, the control circuit 501 may be used as a control circuit of the variable gain amplification device, or may be independently used as a variable resistor. Specifically, the control circuit 501 may be embedded in a device other than a variable gain amplification device.

### Fifth Exemplary Embodiment

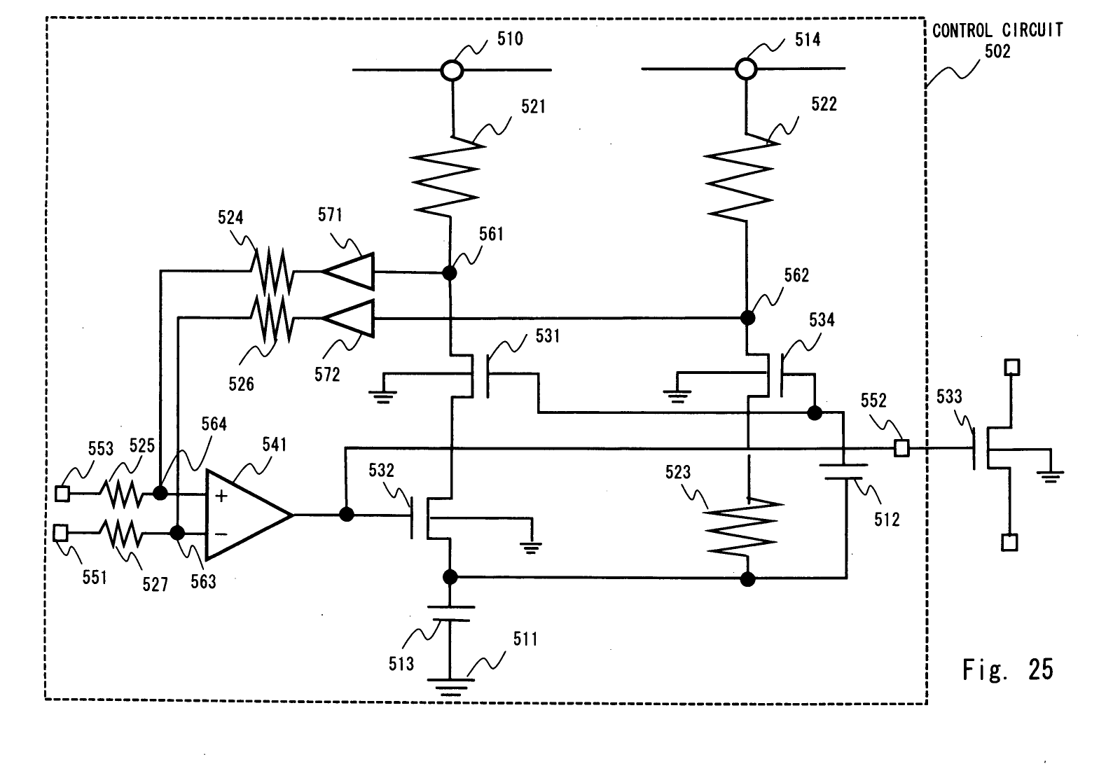

Next, a control circuit 502 according to a fifth exemplary embodiment of the present invention is explained with reference to FIG. 25. The control circuit 10 can be composed by using the control circuit 502. In addition to the configuration of FIG. 22, the control circuit 502 of FIG. 25 includes a power supply (VCC) 514, resistors 522 to 527, a MOS transistor 534, an input terminal 553, and voltage buffers 571 and 572.

The resistors 522 and 523, and a MOS transistor 534 are connected in series between the power supply (VCC) 514 and the source of the MOS transistor 532. As for the resistor 522, one side is connected to the power supply (VCC) 514, and the other side is connected to the MOS transistor 534. As for the resistor 523, one side is connected to the source of the MOS transistor 532 and the bias power supply 512, and the other side is connected to the MOS transistor 534. The MOS transistor 534 is connected between the resistors 522 and 523.

A node 562 outputs a voltage at a node of the resistor 522 and the MOS transistor 534 to the negative terminal side of the operational amplifier 541. The operational amplifier 541 receives the voltage in the negative terminal according to the output voltage from the node 562 and the control voltage Vcnt input to the input terminal 551. At this time, the voltage output by the node 562 is output to a node 563 via the voltage buffer 572 and a resistor 526. The control voltage Vcnt input into the input terminal 551 is output to the node 563 via the resistor 527. The node 563 divides the voltage determined by the voltage output by the node 562 and the control voltage Vcnt using the resistors 526 and 527, and outputs the divided voltage to the negative terminal of the operational amplifier 541.

The node 561 outputs the voltage at the node of the resistor 521 and the MOS transistor 531 to the positive terminal side of the operational amplifier 541. The operational amplifier 541 receives the voltage into the positive terminal of the operational amplifier 541 according to the output voltage form the node 561 and a control voltage Vcent input into the input terminal 553. At this time, the voltage output by the node 561 is output to a node 564 via the voltage buffer 571 and a resistor 524. The control voltage Vcent input into the input terminal 553 is output to the node 564 via a resistor 525. The node 564 divides the voltage determined by the voltage output by the node 561 and the control voltage Vcent using the resistors 524 and 525, and outputs the divided voltage to the negative terminal of the operational amplifier 541.

Further, each pair of the resistors 521 and 522, the resistors 524 and 526, and the resistors 525 and 527 has substantially the same resistance value. This is merely an example, and various values can be specified to these resistances.

Next, an operation of the control circuit 502 of FIG. 25 is explained. A slope of the change in the source-to-drain conductance of the MOS transistor 532 for the control voltage Vcnt is determined to be constant in proportion to R525/(R521×R524) by a feedback loop determined by a ratio of the resistance of the resistors 524 and 525 and a ratio of the resistance of the resistors 526 and 527. In this example, R521 indicates the resistance of the resistor 521, R524 indicates the resistance of the resistor 524, and R525 indicates the resistance of the resistor 525. When the control voltage Vcnt, which is equivalent to the control voltage Vcent, is input to the input terminals 551 and 553, the operation is performed so that the current generated in the resistors 521 and 522 will be the same value by the feedback. The bias power supply 512 is connected to the gate of the MOS transistors 531 and 534 so that they operate in the saturation operation. Therefore, the potential of the sources of the MOS transistors 531 and 534 is determined to be a substantially fixed value. Thus, the source-to-drain conductance of the MOS transistor 532 is determined to be substantially a constant value. Then, the current flowing into the resistor 523, which is determined by the resistor 523, the MOS transistor 534, and the bias voltage 512 is mirrored to flow also into the MOS transistor 532. Thus the resistance and the conductance of the MOS transistor 532 corresponding to the resistor 523 are determined to be a constant value by R523.

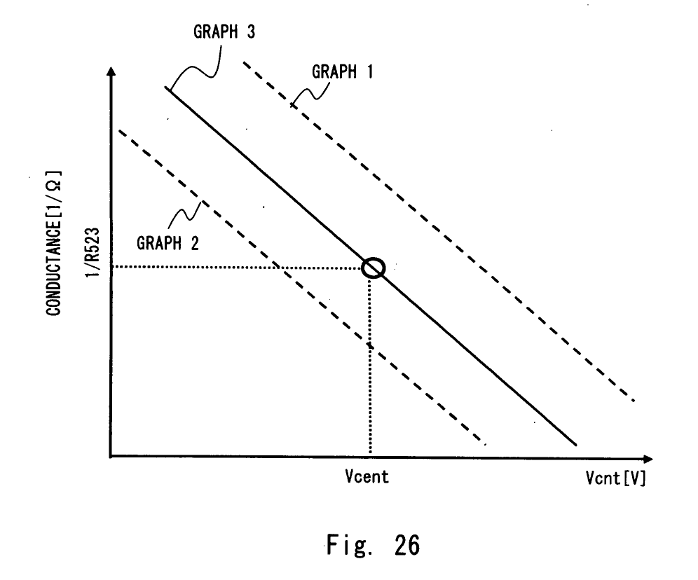

As described so far, by the control circuit 502 according to the fifth exemplary embodiment of the present invention, the slope of the change in the source-to-drain conductance of the MOS transistor 532 for the control voltage Vcnt can be determined to be constant in proportion to R525/(R521×R524). Thus, in a similar manner as the fourth exemplary embodiment, the source-to-drain conductance of the MOS transistor 532 can be linearly controlled. Moreover, the source-to-drain resistance of the MOS transistor 532 when the control voltage Vcnt equals the control voltage Vcent can be determined by R523. Then, the relationship between the conductance and Vcnt, which can be fluctuated by the environmental fluctuation and process variation as in graphs 1 and 2 of FIG. 26 can be uniquely set to a graph 3 in which the conductance is 1/R523 when the control voltage Vcnt equals the control voltage Vcent. In connection with this, the change in the source-to-drain conductance of the MOS transistor 533, which is connected to the operational amplifier 541, can be linearly and uniquely controlled.

### Other Exemplary Embodiment

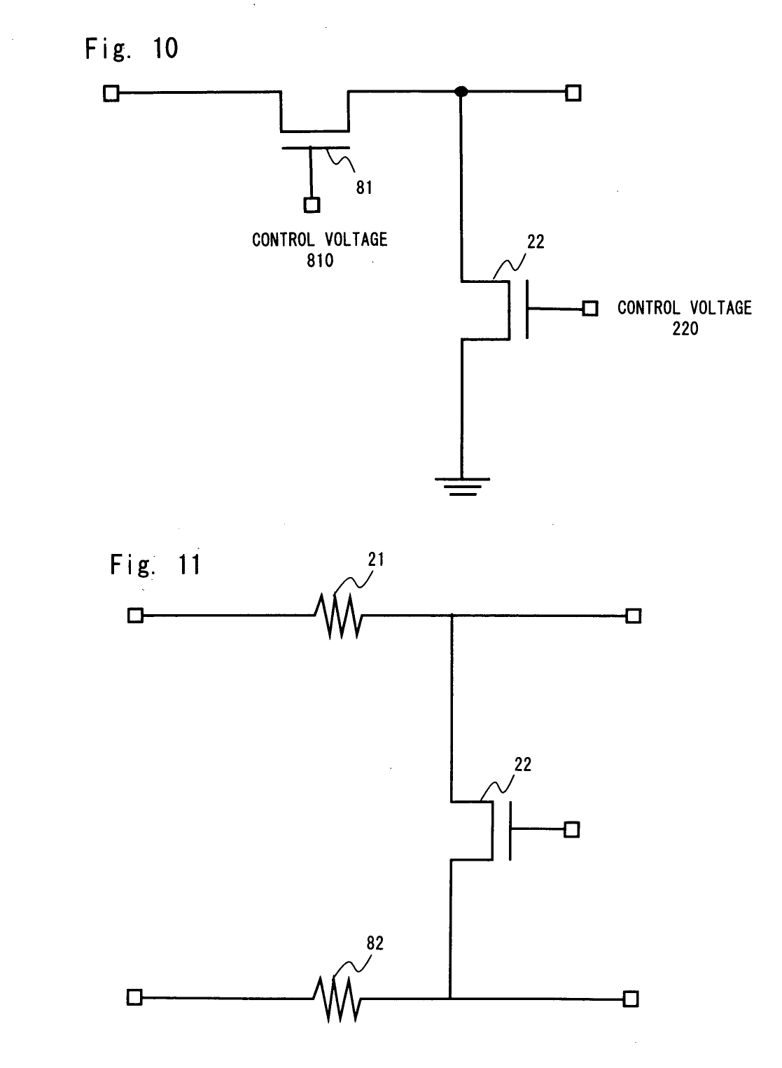

Next, a configuration example of the variable attenuator 20 is explained with reference to FIG. 10. The variable attenuator 20 in FIG. 10 includes a MOS transistor 81 instead of the resistor 21 of the variable attenuator 20 of FIG. 3. The source or the drain of the MOS transistor 81 is connected to an input terminal, and the other one of the source or the drain of the MOS transistor 81 is connected to the output terminal of the variable gain amplifier 30. Thus, the amount of attenuation can be changed by complementarily controlling the two control voltages, such that at the same time as reducing the source-to-drain resistance of the MOS transistor 22 by increasing the control voltage 220 of the MOS transistor 22, increasing the source-to-drain resistance of the MOS transistor 81 by reducing control voltage 810 of the MOS transistor 81.

Next, a configuration example when the variable attenuator 20 is a differential input is explained with reference to FIG. 11. The variable attenuator 20 in FIG. 11 further includes a resistor 82 in addition to the configuration of the variable attenuator 20 of FIG. 3. The resistor 82 is connected to the source or the drain of the MOS transistor 22, which is different from the one connected to the resistor 21. Since the operation is the same as that of the first exemplary embodiment, the explanation is omitted.

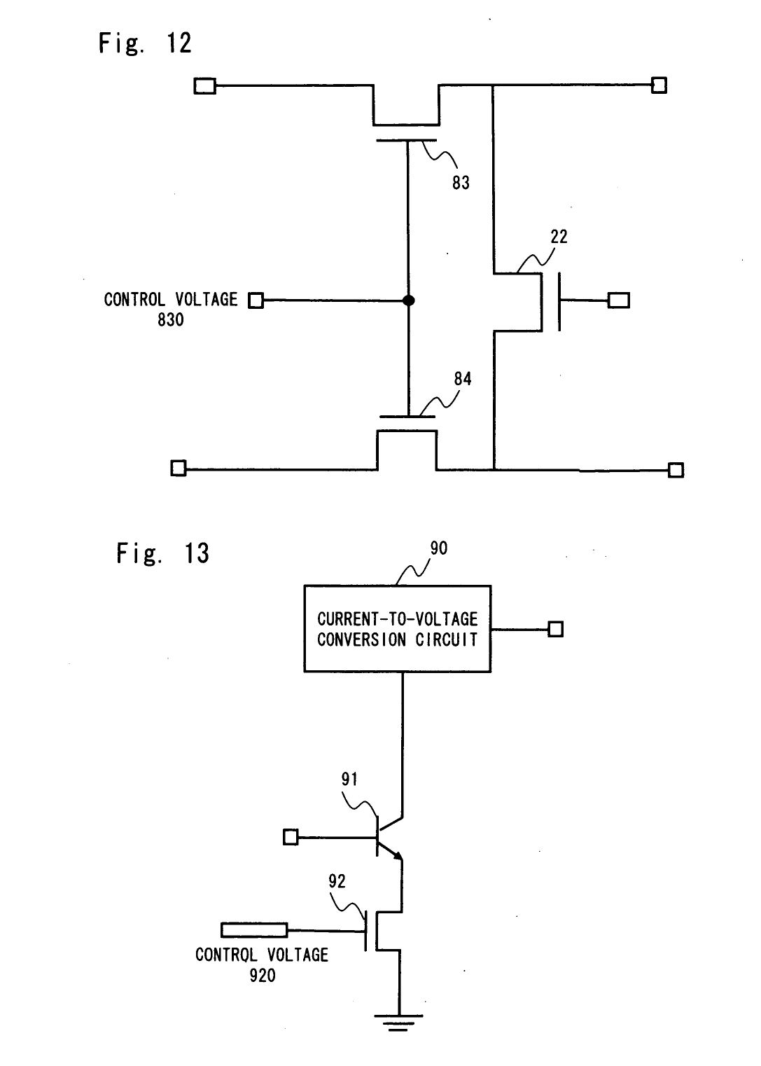

Next, another configuration example when the variable attenuator 20 is a differential input is explained with reference to FIG. 12. The variable attenuator 20 of FIG. 12 includes MOS transistors 83 and 84 instead of the resistors 21 and 82 of FIG. 11. The MOS transistors 83 and 84 perform variable control to the source-to-drain resistance by a control voltage 830. Since the operation is the same as that of the variable attenuator 20 of FIG. 10, the explanation is omitted.

Next, a configuration example of the variable gain amplifier 30 is explained with reference to FIG. 13. The variable gain amplifier 30 includes a current-to-voltage conversion circuit 90, a bipolar transistor 91, and a MOS transistor 92. The signal output by the variable attenuator 20 is connected to the base of the bipolar transistor 91. Further, the current-to-voltage conversion circuit 90 is connected to the collector of the bipolar transistor 91, and the drain of the MOS transistor 92 is connected to the emitter of the bipolar transistor 91. The source of the MOS transistor 92 is grounded. The gain obtained by the variable gain amplifier 30 can be changed by changing the source-to-drain resistor of the MOS transistor 92 by a control voltage 920, which is emitter resistor of the bipolar transistor 91. Furthermore, if bias current of the bipolar transistor 91 is set constant, and conversion gain of the current-to-voltage conversion circuit 90 is set constant, a constant 1 dB compression point characteristic can be obtained.

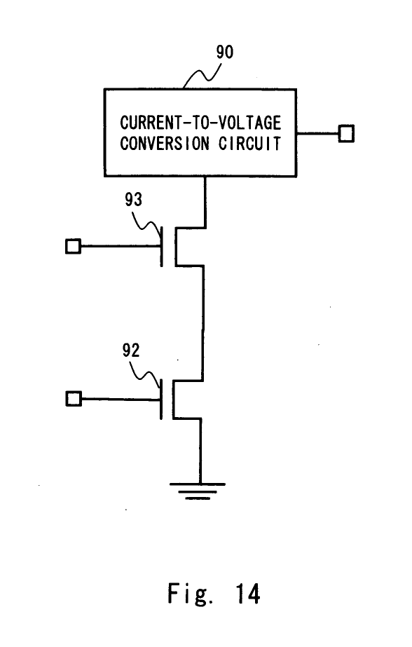

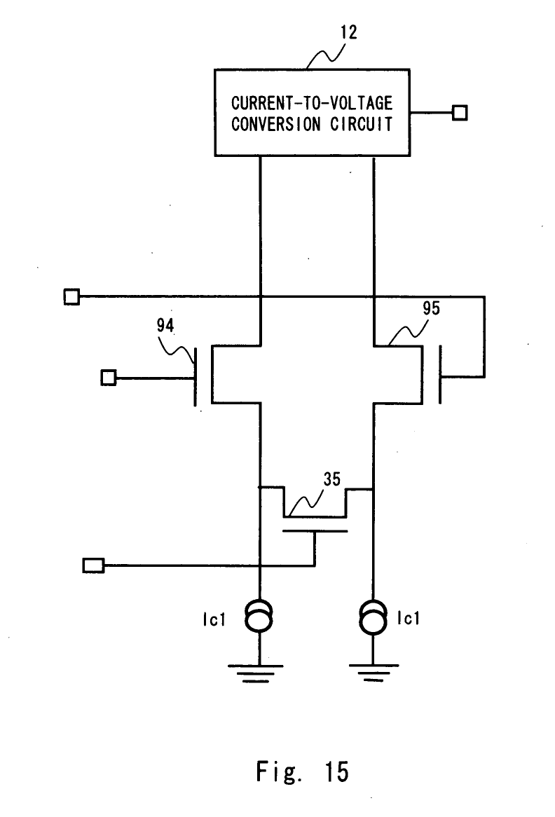

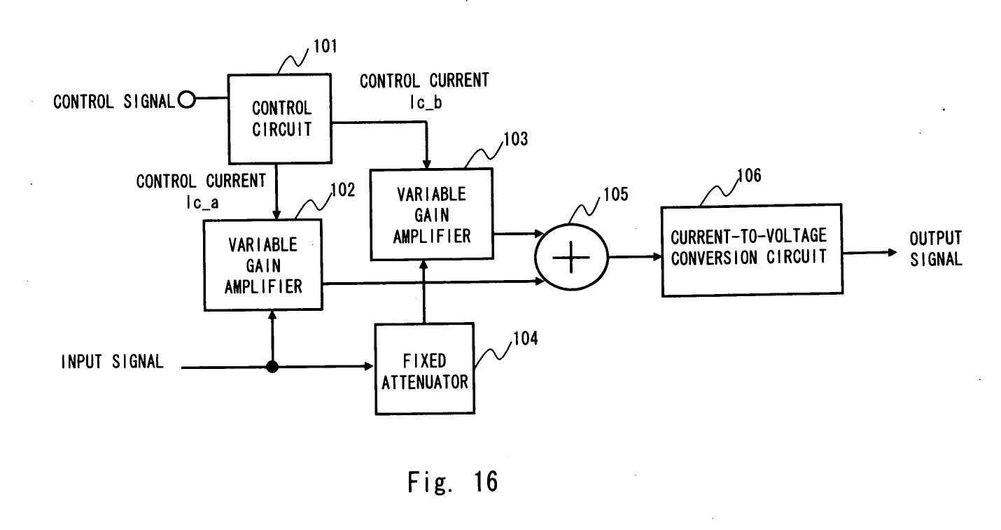

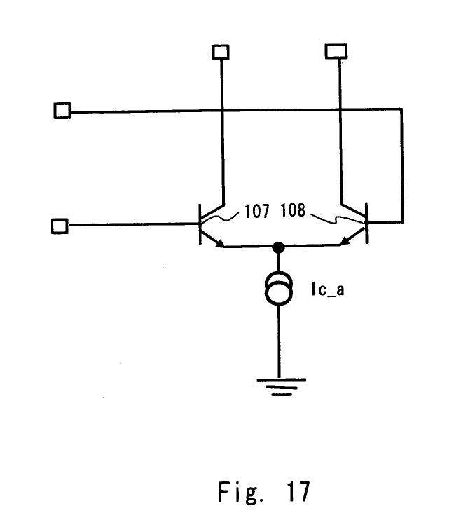

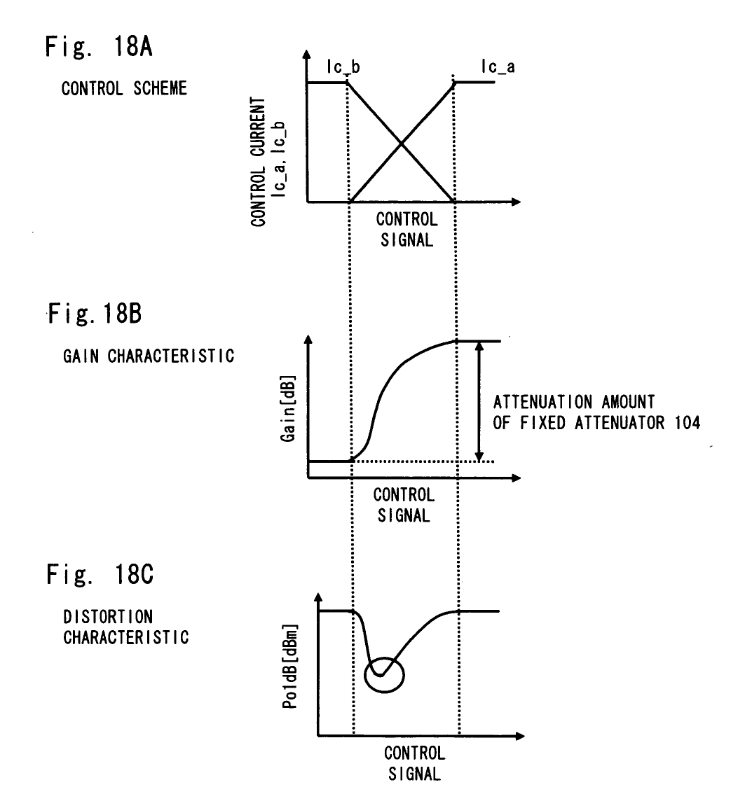

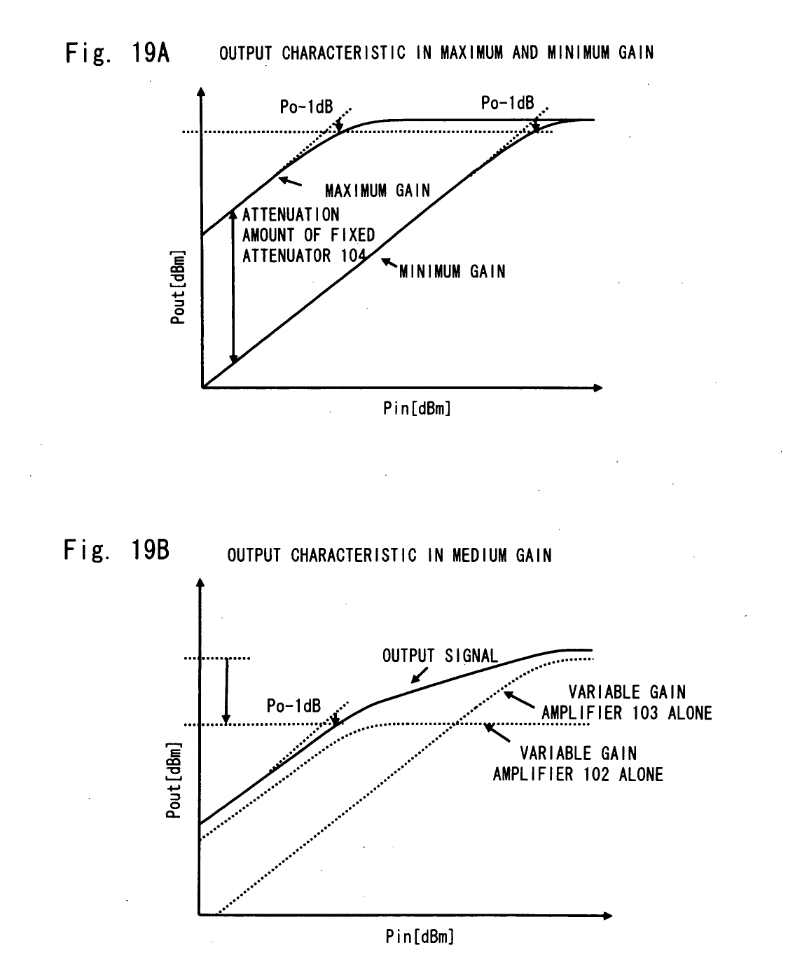

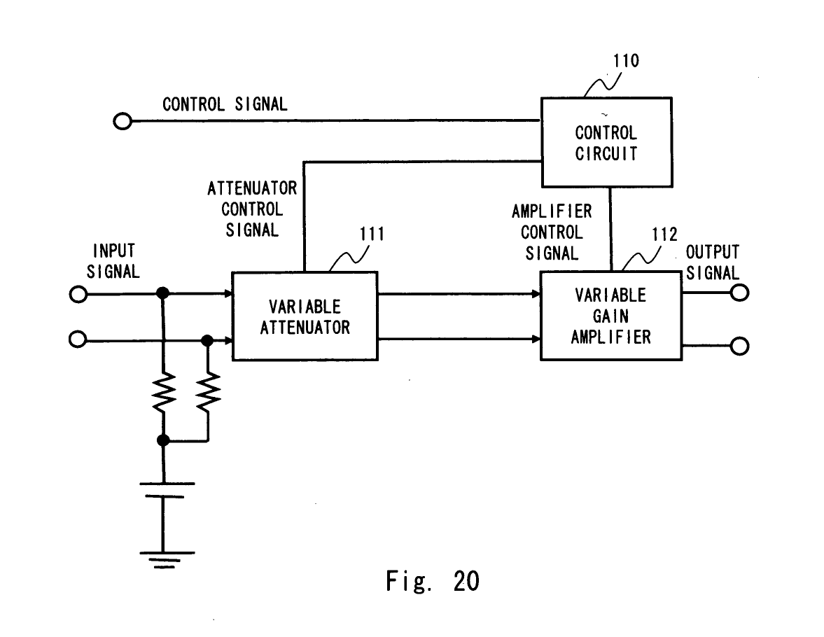

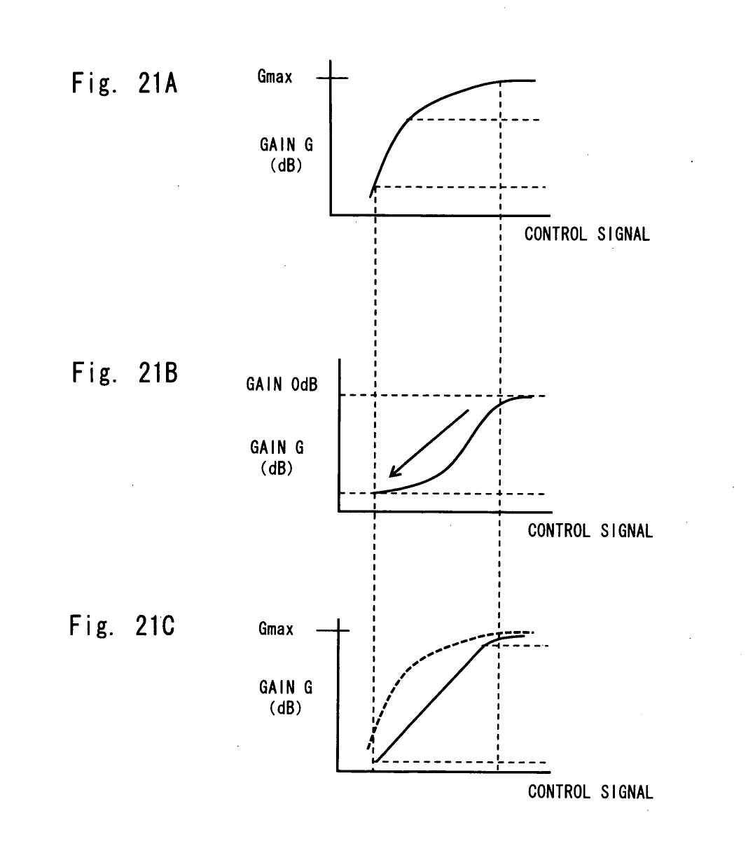

Next, another configuration example of the variable gain amplifier 30 is explained with reference to FIG. 14. The variable gain amplifier 30 of FIG. 14 includes a MOS transistor 93 instead of the bipolar transistor 91 of FIG. 13. Since the operation is the same as that of the variable gain amplifier 30 of FIG. 14, the explanation is omitted.

Next, another configuration example of the variable gain amplifier 30 is explained with reference to FIG. 15. The variable gain amplifier 30 of FIG. 15 includes MOS transistors 94 and 95 instead of the bipolar transistors 32 and 33 of the variable gain amplifier 30 of FIG. 3. Since the operation is the same as that of the variable gain amplifier 30 of FIG. 3, the explanation is omitted.

As explained above, various circuit configurations can be combined for the variable attenuator 20 and the variable gain amplifier 30 depending on the target characteristic.

The present invention is not limited to the above exemplary embodiments, but can be modified as appropriate without departing from the scope of the present invention.

The first, second, third, fourth, fifth and other exemplary embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A variable gain amplification device comprising:
a variable attenuation unit that attenuates an input signal;
a first variable gain amplification unit that changes and amplifies a gain of the attenuated input signal, the input signal being output by the variable attenuation unit; and
a control unit that controls to fix an amount of attenuation of the variable attenuation unit in a first control region in which the first variable gain amplification unit changes the gain.

2. The variable gain amplification device according to claim 1, wherein the control unit
controls to change the amount of attenuation of the variable attenuation unit in a second control region in which the gain is fixed by the first variable gain amplification unit, and
controls to change the amount of attenuation of the variable attenuation unit in a third control region in which the first variable gain amplification unit shifts the gain from the second control region to the first control region.

3. The variable gain amplification device according to claim 2, wherein
the first control region is a region in which the gain of an output signal from the first variable gain unit is greater than a first threshold,
the second control region is a region in which the gain of the output signal from the first variable gain unit is lower than a second threshold which indicates the gain smaller than the first threshold, and
the third control region is a region in which the gain of the output signal from the first variable gain unit is lower than the first threshold and greater than the second threshold.

4. The variable gain amplification device according to claim 3, wherein
the variable attenuation unit and the first variable gain amplification unit comprise a MOS transistor, and
the control unit controls the amount of attenuation of the variable attenuation unit and an amount of change in the gain of the variable gain amplification unit by outputting a control voltage to the MOS transistor included in the variable attenuation unit and the first variable gain amplification unit.

5. The variable gain amplification device according to claim 4, wherein the control unit
in a case of the first control region, outputs a variable control voltage to the first variable gain amplification unit, and outputs a fixed control voltage to the variable attenuation unit,
in a case of the second control region, outputs the fixed control voltage to the first variable gain amplification unit, and outputs the variable control voltage to the first variable attenuation unit, and
in a case of the third control region, outputs the variable control voltage to the first variable gain amplification unit and the variable attenuation unit.

6. The variable gain amplification device according to claim 1, further comprising:
a second variable gain amplification unit that is connected in parallel to the variable attenuation unit and amplifies the gain of the obtained input signal; and
an output signal generation unit that generates the output signal according to the signal with the amplified gain, which is output by the first variable gain amplification unit and the second variable gain amplification unit.

7. The variable gain amplification device according to claim 6, wherein the control unit, in the case of the first control region, reduces the gain of the first variable gain amplification unit and amplifies the gain of the second variable gain amplification unit.

8. The variable gain amplification device according to claim 1, wherein the control unit comprises:
a first resistor unit that is provided between a first power supply and a second power supply, and connected to the first power supply, the second power supply including lower potential than the first power supply;
a first MOS transistor that is provided between the first power supply and the second power supply, and connected in series to the first resistor unit;
a second MOS transistor that is provided between the first MOS transistor and the second power supply, and connected in series to the first MOS transistor; and
an operational amplifier that outputs a gate voltage to the second MOS transistor according to a voltage at a node of the first resistor unit and the first MOS transistor and a first control voltage,
wherein the operational amplifier outputs the gate voltage to an external variable resistor with resistance controlled according to the gate voltage.

9. The variable gain amplification device according to claim 8, wherein the first MOS transistor operates in a saturation region and the second MOS transistor operates in a linear region.

10. The variable gain amplification device according to claim 9, further comprising a first bias power supply that supplies a bias voltage to the first MOS transistor and the second MOS transistor so that the first MOS transistor operates in the saturation region and the second MOS transistor operates in the linear region.

11. The variable gain amplification device according to claim 8, wherein the operational amplifier outputs the gate voltage to a variable resistor that uses an external third MOS transistor with resistance controlled according to the gate voltage.

12. The variable gain amplification device according to claim 8, further comprising a second bias power supply that is connected to the second MOS transistor so that a potential of one sides of the second MOS transistor and the third MOS transistor will be same.

13. The variable gain amplification device according to claim 8, further comprising:
a second resistor unit that is provided between a third power supply and the second power supply, and connected to the third power supply;
a fourth MOS transistor that is provided between the third power supply and the second power supply, and connected in series to the second resistor unit; and
a third resistor unit that is connected in series to the fourth MOS transistor and a node of the second MOS transistor and the second power supply,
wherein the operational amplifier receives a first input voltage and a second input voltage, in which the first input voltage is determined by a voltage at a node of the second resistor unit and the fourth MOS transistor and the first control voltage, and the second input voltage is determined by a voltage at a node of the first resistor unit and the first MOS transistor and the second control voltage.

14. The variable gain amplification device according to claim 13, wherein when the first control voltage and the second control voltage are same, resistance of the second MOS transistor is determined by resistance of the third resistor unit.

15. The variable gain amplification device according to claim 13, wherein
the first input voltage is divided by a fourth resistor unit and a fifth resistor unit which are connected in series between the node of the second resistor unit and the fourth MOS transistor and an input terminal for receiving the first control voltage, and
the second input voltage is divided by a sixth resistor unit and a seventh resistor unit which are connected in series between the node of the first resistor unit and the first MOS transistor and the input terminal for receiving the second control voltage.

16. A control circuit comprising:
a variable attenuation unit that attenuates an input signal;
a first variable gain amplification unit that changes and amplifies a gain of the attenuated input signal, the input signal being output by the variable attenuation unit; and
a control unit that controls to fix an amount of attenuation of the variable attenuation unit in a first control region in which the first variable gain amplification unit changes the gain.
